(19) United States
(12) Patent Application Publication
(10) Pub. No.: US 2026/0011557 A1
(43) Pub. Date: Jan. 8, 2026

(54) METHOD FOR PRODUCING A SEMICONDUCTOR BODY, SEMICONDUCTOR BODY AND POWER SEMICONDUCTOR DEVICE

(71) Applicant: Hitachi Energy Ltd, Zürich (CH)

(72) Inventors: Yulieth Cristina ARANGO, Zürich (CH); Giovanni ALFIERI, Möriken (CH)

(21) Appl. No.: 19/111,130

(22) PCT Filed: Sep. 16, 2022
(86) PCT No.: PCT/EP2022/075766

§ 371 Date: Mar. 12, 2025

(51) Int. Cl. H01L 21/04; C30B 25/18; C30B 25/20; C30B 31/22; H01L 21/02

(52) U.S. Cl. CPC H01L 21/046; C30B 25/183; C30B 25/186; C30B 25/20; C30B 31/22; H01L 21/02529

(57) ABSTRACT

A method for producing a semiconductor body comprises providing a first semiconductor layer of SiC, introducing carbon into the first semiconductor layer so that at least a portion of the first semiconductor layer becomes at least one C-rich region, and growing a second semiconductor layer of SiC on the first semiconductor layer comprising the at least one C-rich region.

The present disclosure relates to a method for producing a semiconductor body, a semiconductor body and a power semiconductor device.

There is a need for an improved method for producing a semiconductor body, for example for a method which allows a semiconductor body with high charge carrier mobility to be produced. A further object to be achieved is to provide an improved semiconductor body, for example with high charge carrier mobility. Another object to be achieved is to provide a power semiconductor device with such a semiconductor body.

Embodiments of the disclosure relate to an improved method for producing a semiconductor body, an improved semiconductor body and an improved power semiconductor device.

According to an embodiment, the method for producing a semiconductor body comprises the step of providing a first semiconductor layer of silicon carbide, SiC for short, a further step of introducing carbon, C for short, into the first semiconductor layer so that at least a portion of the first semiconductor layer becomes at least one carbon rich region, C-rich region for short, and a step of growing a second semiconductor layer of SiC on the first semiconductor layer comprising the at least one C-rich region.

The present invention is, inter alia, based on the recognition that carbon vacancies are the most important point defects of SiC, for example of n-type 4H-SiC. Carbon vacancies give rise to two electrically active levels in the bandgap labelled Z_{1/2} and EH_{6/7} and located at 0.65 eV and 1.6 eV below the conduction band edge, respectively. In particular, Z_{1/2} is known to be a recombination center, affecting the lifetime in bipolar devices.

The inventors of the present invention had the idea to form at least one C-rich region inside a semiconductor layer sequence. This C-rich region will eventually release carbon from interstitials, which will then anneal out the carbon vacancies. Due to the fact that the at least one C-rich region is formed during the formation of the semiconductor layer sequence, i.e. after the first semiconductor layer is provided and before the second semiconductor layer is grown, the C-rich region can be formed inside the semiconductor layer sequence and can therefore more efficiently provide all regions of the semiconductor layer sequence with carbon from carbon interstitials.

Furthermore, the formation of the at least one C-rich region during the formation of the semiconductor layer sequence, as proposed herein, is beneficial compared to forming the C-rich region after the semiconductor layer sequence has been completely grown. This is because, in the second case, forming the C-rich region inside the semiconductor layer sequence would have to be done by deep C-ion implantation, which requires high implantation energies. This makes the process expensive and also amorphizes the crystal and thus creates more electrically active levels. The method proposed herein is less expensive and gentler, i.e. produces much less active levels compared to deep ion implantation.

The first semiconductor layer may be provided as a contiguous layer, for example without interruptions. Providing the first semiconductor layer may comprise the step of growing, e.g. epitaxially growing, the first semiconductor layer on a substrate. The first semiconductor layer may be grown by Chemical Vapor Deposition, CVD for short. The substrate is, for example, made of SiC. The substrate may be doped, e.g. n-doped. The doping concentration in the substrate may be at least 10¹⁸ cm⁻³.

The thickness of the first semiconductor layer is, for example, at least 1 μm or at least 2 μm or at least 5 μm. Additionally or alternatively, the thickness of the first semiconductor layer may be at most 30 μm or at most 20 μm. The thickness of the substrate may be greater than the thickness of the first semiconductor layer. For example, the thickness of the substrate is at least 100 μm or at least 300 μm and/or at most 600 μm or at most 400 μm.

Herein, the thickness of a layer, region or substrate is meant to be its extension in vertical direction, i.e. in a direction perpendicular to the main extension plane of the first semiconductor layer. The SiC of the different semiconductor layers and/or of the substrate mentioned herein is, for example, 4H-SiC, particularly n-doped 4H-SiC.

The first semiconductor layer may be doped, e.g. n-doped. For example, the average and/or maximum doping concentration in the first semiconductor layer is smaller than the average and/or minimum doping concentration in the substrate, e.g. by at least one or at least two or at least three orders of magnitude. By way of example, the average doping concentration in the first semiconductor layer is between 10¹⁴ cm⁻³ and 10¹⁷ cm⁻³. The first semiconductor layer may already be n-doped when it is provided. For example, the first semiconductor layer is doped during its growth.

The step of introducing carbon into the first semiconductor layer is done such that at least a portion of the first semiconductor layer becomes at least one C-rich region. A C-rich region is herein understood as a region in which the carbon concentration is greater than in an ideal SiC crystal.

In a C-rich region, the additional carbon atoms (C-atoms) or carbon ions (C-ions) are located at interstitial sites, for example.

For instance, a C-rich region is herein defined as a region in which the minimum and/or average concentration of C-atoms or C-ions, respectively, at interstitial sites is at least 100-times or at least-1000 times or at least-10000 times greater than the maximum and/or average concentration in the rest of the first semiconductor layer or than in the first semiconductor layer before the step of introducing carbon has been performed, respectively. The carbon at the interstitial sites is usually charged, so it is mainly C-ions at the interstitial sites.

Herein, a minimum concentration in or of a region or layer or the like is meant to be the lowest concentration one can find in said region, layer etc. Accordingly a maximum concentration in or of a region, layer etc. is meant to be the highest concentration one can find in said region, layer etc. An average concentration in or of a region, layer etc. is the concentration averaged over the whole volume of said region, layer etc.

For example, only a portion of but not the complete first semiconductor layer becomes a C-rich region. By way of example, only the region at an exposed surface, through which the carbon enters into the first semiconductor layer, becomes C-rich. For example, at most 10% or at most 5% or at most 1% of the volume of the first semiconductor layer becomes the at least one C-rich region.

“At least one C-rich region” means that only one contiguous region of the first semiconductor layer becomes a C-rich region or, alternatively, that a plurality of spatially separated regions of the first semiconductor layer each becomes a C-rich region. All features disclosed herein for one C-rich region are also disclosed for all other C-rich regions.

Introducing the carbon into the first semiconductor layer may be done by C-ion implantation or by annealing in a C-rich ambient, e.g. CO₂, CH₄ etc., or by PIII, for example. Once, the carbon is introduced, it may be diffused by thermal annealing.

The second semiconductor layer is also made of SiC and is grown on the first semiconductor layer after the at least one C-rich region has been formed. That is, the second semiconductor layer is grown on the first semiconductor layer already comprising the at least one C-rich region. The second semiconductor layer is, in particular, grown such that it covers the at least one C-rich region partially or completely. The main extension plane of the second semiconductor layer may be parallel to that of the first semiconductor layer.

The second semiconductor layer may be epitaxially grown on the first semiconductor layer. For example, the second semiconductor layer is directly grown on the first semiconductor layer, i.e. adjoins the first semiconductor layer, particularly the at least one C-rich region. The growing technique may be the same as that used for the first semiconductor layer.

After its growth, the second semiconductor layer may have a thickness of at least 2 μm or at least 5 μm. Additionally or alternatively, the thickness of the second semiconductor layer may be at most 30 μm or at most 20 μm. The second semiconductor layer may be grown as a contiguous layer, for example without interruptions. It may extend over the whole lateral extension of the first semiconductor layer. Herein, lateral directions are directions parallel to the main extension plane of the first semiconductor layer.

During growth, the second semiconductor layer may be doped, e.g. n-doped. The doping concentrations are, for example, the same as specified in connection with the first semiconductor layer.

According to a further embodiment, the C-rich region is formed at an exposed side of the first semiconductor layer. That is, the C-rich region is formed such that it adjoins the top side of the first semiconductor layer through which the carbon is introduced and on which the second semiconductor layer is grown afterwards.

According to a further embodiment, the C-rich region is formed such that after growing the second semiconductor layer, the C-rich region lies between the second semiconductor layer and a remaining portion of the first semiconductor layer which has not be become C-rich. In other words, the C-rich region is formed such that it does not extend over the whole thickness of the first semiconductor layer. For example, the depth (thickness) of the C-rich region is at most 10% or at most 5% or at most 1% of the thickness of first semiconductor layer.

According to a further embodiment, the carbon is introduced into the first semiconductor layer using plasma ion immersion implantation, PIII for short. PIII is a particularly gentle implantation method producing very shallow implantation regions, i.e. implantation regions of small depth (thickness). The use of PIII can be detected by SIMS in the final semiconductor body due to the peculiar implantation shape generated by PIII and by the presence of extra species coming from the used precursor(s).

According to a further embodiment, the method comprises a further step of implanting first-type dopants into the semiconductor layer sequence, said semiconductor layer sequence comprising the first and the second semiconductor layer. That is, the first-type dopants are implanted after the second semiconductor layer has been grown. The semiconductor layer sequence, into which the first-type dopants are implanted, may comprise one or more additional semiconductor layers in addition to the first and the second semiconductor layer. For example, before growing the first semiconductor layer and/or after growing the second semiconductor layer, at least one further semiconductor layer is grown.

For instance, the implantation of the first-type dopants is performed after the growth of the semiconductor layer sequence has been finished, i.e. after all growth steps for producing the semiconductor body have been performed. For example, the first-type dopants are implanted into the semiconductor layer sequence via a side of the semiconductor layer sequence which is closer to the second semiconductor layer than to the first semiconductor layer. For instance, the first-type dopants are implanted at such a depth that they do not reach the C-rich region(s) and/or the first semiconductor layer. For example, the first-type dopants are implanted into the second semiconductor layer. The first-type dopants may be p-type dopants, e.g. Boron. For example, p-wells are formed in the step of implanting the first-type dopants.

According to a further embodiment, the first-type dopants are activated at a temperature of at least 1000° C. or at least 1500° C. Additionally or alternatively, the temperature for activating the first type dopants may be at most 1800° C. or at most 1700° C.

Heating the semiconductor layer sequence to such temperatures also releases the carbon at the interstitial sites of the C-rich region. The released carbon will then recombine with the carbon vacancies created during the implantation of the first-type dopants and/or with the pre-existing carbon vacancies.

Additionally or alternatively, the semiconductor layer sequence may be heated up to the above-mentioned temperatures independently of the implantation of the first-type dopants. For example, the semiconductor layer sequence may be heated up to these temperatures before implantation of the first-type dopants or even in the case that an implantation of dopants is not executed at all. This heating has the same effect of carbon being released from interstitial sites and eventually combining with the carbon vacancies.

According to a further embodiment, implantation is done with an energy of the C-ions in the range between 0.5 keV inclusive and 100 keV inclusive, for example between 1 keV inclusive and 50 keV inclusive. With such implantation energies, the damage caused by the implantation can be kept small.

According to a further embodiment, the minimum and/or average concentration of C-atoms or C-ions at interstitial sites is at least 10¹⁴ cm⁻³ or at least 10¹⁶ cm⁻³ or at least 10¹⁷ cm⁻³ or at least 10¹⁸ cm⁻³ in the C-rich region. Additionally or alternatively, the maximum concentration of C-atoms or C-ions at interstitial sites is at most 10²¹ cm⁻³ in the C-rich region. Particularly, a C-rich region can be defined as a region in which this minimum concentration is present everywhere inside that region or as a region which has this average concentration.

According to a further embodiment, at least one buffer region of the second semiconductor layer adjoins the C-rich region and is doped with second-type dopants. The second-type dopants are, for example, n-type dopants. Particularly, the second-type dopants are different from the first type dopants, i.e. of the opposite conductivity type.

According to a further embodiment, the minimum and/or average concentration of the second-type dopants in the at least one buffer region of the second semiconductor layer is greater than a maximum and/or average concentration of second-type dopants in the first semiconductor layer. For example, the minimum and/or average concentration of the second-type dopants in the buffer region is at least 10 times or at least 100 times or at least 1000 times greater than the maximum and/or average concentration of second-type dopants in the first semiconductor layer. The minimum and/or average concentration of second-type dopants in the buffer region is, for example, at least 10¹⁶ cm⁻³ or at least 10¹⁷ cm⁻³. Additionally or alternatively, the maximum and/or average concentration of second-type dopants in the buffer region may be at most 10¹⁹ cm⁻³ or at most 10¹⁸ cm⁻³. Also in this case, the buffer region may be defined by the region in which said conditions for the minimum doping concentration are fulfilled everywhere or which fulfills the condition for the average concentration.

The buffer region may be a buffer layer extending contiguously, e.g. without interruptions, over the whole lateral extent of the second semiconductor layer.

The C-rich regions may result in strains in the crystal lattice. The buffer region can compensate these strains and can, for example, improve the growth conditions for the rest of the second semiconductor layer.

According to a further embodiment, a plurality of C-rich regions which are laterally spaced from each other is formed in the first semiconductor layer. The plurality of C-rich regions is formed in the step of the introduction of carbon into the first semiconductor layer, e.g. by C-ion implantation. The C-rich regions of the first semiconductor layer may all be arranged at the same height with respect to the main extension plane of the first semiconductor layer. That is, a plane parallel to the main extension plane of the first semiconductor layer intersects with each of the C-rich regions in the first semiconductor layer.

For example, each of the C-rich regions has a lateral extension which is at most 2 μm or at most 1 μm and/or at least 0.5 μm. The distance between each two adjacent C-rich regions measured in lateral direction is, for example, at most 5 μm or at most 2 μm and/or at least 0.5 μm. The C-rich regions may be arranged on grid points of a regular grid. For example, each C-rich region is a rectangular region or circular region when viewed in plan view onto the side of the first semiconductor layer on which the second semiconductor layer is grown. Alternatively, the C-rich regions of the first semiconductor layer may be formed as stripes, which, for example, run parallel to each other.

Forming a plurality of C-rich regions may be done by using a mask, e.g. during the C-ion implantation process.

According to a further embodiment, the method comprises a step of introducing carbon into the second semiconductor layer so that at least a portion of the second semiconductor layer becomes at least one C-rich region. All features disclosed in connection with the at least one C-rich region of the first semiconductor layer are also disclosed for that at least one C-rich region of the second semiconductor layer.

For example, the C-rich region(s) in the second semiconductor layer may be formed using the same method as used for forming the C-rich region(s) in the first semiconductor layer, for example PIII.

According to a further embodiment, the method comprises a step of growing a third semiconductor layer of SiC on the second semiconductor layer. For example, the third semiconductor layer is epitaxially grown. All features disclosed in connection with the second semiconductor layer are also disclosed for the third semiconductor layer, particularly concerning doping and thickness.

According to a further embodiment, a plurality of C-rich regions which are laterally spaced from each other is formed in the second semiconductor layer. The features disclosed in connection with the plurality of C-rich regions in the first semiconductor layer are also disclosed for the plurality of C-rich regions in the second semiconductor layer.

According to a further embodiment, the C-rich regions in the first semiconductor layer and the C-rich regions in the second semiconductor layer are arranged in a staggered configuration. This means, in particular, that the C-rich regions of the first semiconductor layer overlap at most partially with the C-rich regions of the second semiconductor layer in at least one lateral direction. For example, the C-rich regions of the first semiconductor layer do not overlap with the C-rich regions of the second semiconductor layer in at least one lateral direction. The C-rich regions of the first semiconductor layer are arranged at a different height than the C-rich regions of the first semiconductor layer with respect to the main extension plane of the first semiconductor layer and, for example, do not overlap with each other in vertical direction.

Next, the semiconductor body is specified. The semiconductor body may, in particular, be produced with the method according to any one of the embodiments described herein. Therefore, all features disclosed in connection with the method are also disclosed for the semiconductor body and vice versa.

According to an embodiment, the semiconductor body comprises a first semiconductor layer of SiC, a second semiconductor layer of SiC on the first semiconductor layer and at least one C-rich region in the first semiconductor layer. The C-rich region adjoins the second semiconductor layer. In the C-rich region, the minimum and/or the average concentration of C-atoms or C-ions at interstitial sites is at least 10¹⁷ cm⁻³. The thickness of the C-rich region is at most 100 nm or at most 50 nm or at most 30 nm and/or at least 10 nm or at least 15 nm. The thickness is thereby measured perpendicular to the main extension plane of first semiconductor layer.

According to a further embodiment, the C-rich region has its maximum concentration of C-atoms or C-ions at interstitial sites at the interface to the second semiconductor layer. For example, the concentration profile in vertical direction, perpendicular to the main extension plane of the first semiconductor layer, is asymmetric with respect to the interface between the first and the second semiconductor layer. For example, the distance, measured in vertical direction, from the interface at which the concentration falls below 0.01 times the maximum concentration is at least two orders of magnitude or at least three orders of magnitude greater in the first semiconductor layer than in the second semiconductor layer. For example, said distance in the first semiconductor layer is at least 5 nm or at least 10 nm and/or at most 30 nm or at most 25 nm. The maximum concentration of C-atoms/C-ions at interstitial sites in the C-rich region may be at least 10¹⁹ cm⁻³ and/or at most 10²¹ cm⁻³.

The thickness of the portion of the C-rich region in which the minimum and/or average concentration of C-atoms/C-ions at interstitial sites is at least 10¹⁸ cm⁻³ may be at most 30 nm or at most 25 nm and/or at least 5 nm or at least 10 nm. The thickness of the portion of the C-rich region in which the minimum and/or average concentration of C-atoms/C-ions at interstitial sites is at least 10¹⁹ cm⁻³ may be at most 20 nm and at least 10 nm.

According to a further embodiment, the maximum and/or average concentration of carbon vacancies, C-vacancies for short, in the second semiconductor layer is at most 10¹² cm⁻³ or at most 10¹¹ cm⁻³. This particularly refers to Z1/2 vacancies.

According to a further embodiment, the average mobility for charge carriers and the second semiconductor layer is at least 100 cm²/Vs or at least 120 cm²/Vs or at least 150 cm²/Vs at room temperature.

The specified concentration of C-vacancies and the specified mobility in the second semiconductor layer may be likewise valid for the first semiconductor layer. In the case of a third semiconductor layer grown on the second semiconductor layer, these values may additionally or alternatively be valid for the third semiconductor layer.

Next, the power semiconductor device is specified.

The power semiconductor device comprises a semiconductor body according to any one of the embodiments described herein. Furthermore, the power semiconductor device comprises electrodes in electrical contact with the semiconductor body. The electrodes may be of metal and/or highly doped poly-silicon. For example, the power semiconductor device is a transistor, like a MOSFET or an IGBT, or a thyristor.

Hereinafter, the method for producing a semiconductor body, the semiconductor body and the power semiconductor device will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures. For the sake of clarity, elements might not appear with corresponding reference symbols in all figures.

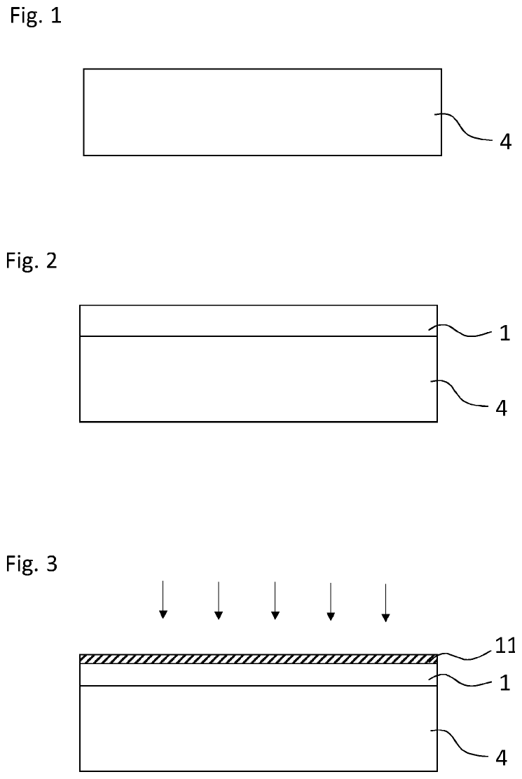

FIGS. 1 to 8 show different positions in a first exemplary embodiment of the method, different exemplary embodiments of the semiconductor body as well as an exemplary embodiment of the power semiconductor device,

FIG. 9 shows DLTS measurement curves,

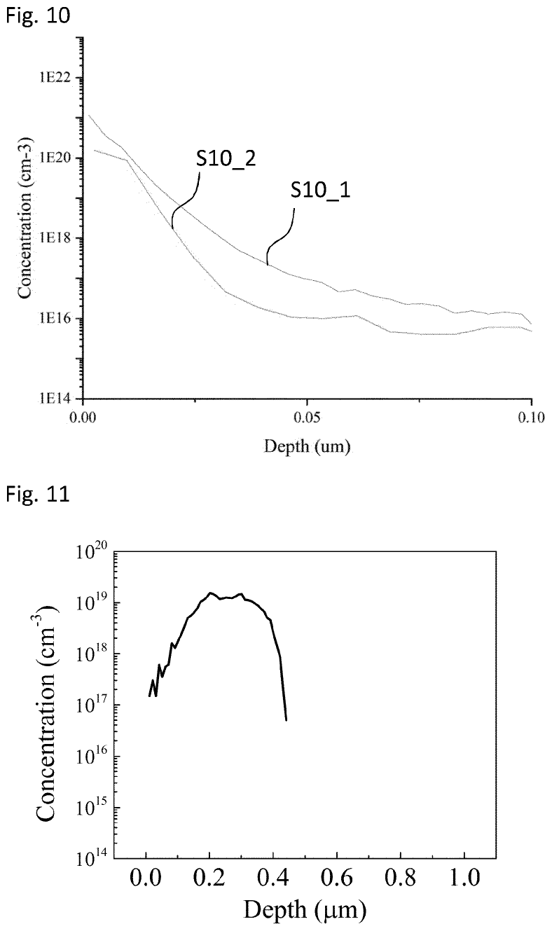

FIG. 10 shows curves of the concentration of C-atoms or C-ions at interstitial sites in a C-rich region produced with PIII,

FIG. 11 shows a curve of the concentration of C-atoms at interstitial sites in a C-rich region produced with deep ion implantation,

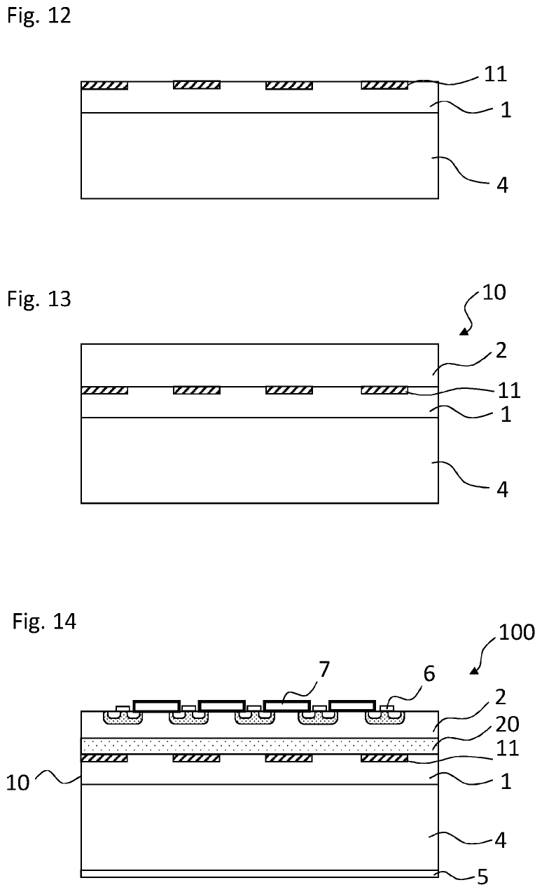

FIGS. 12 to 14 show different positions in a second exemplary embodiment of the method as well as exemplary embodiments of the semiconductor body and an exemplary embodiment of the power semiconductor device,

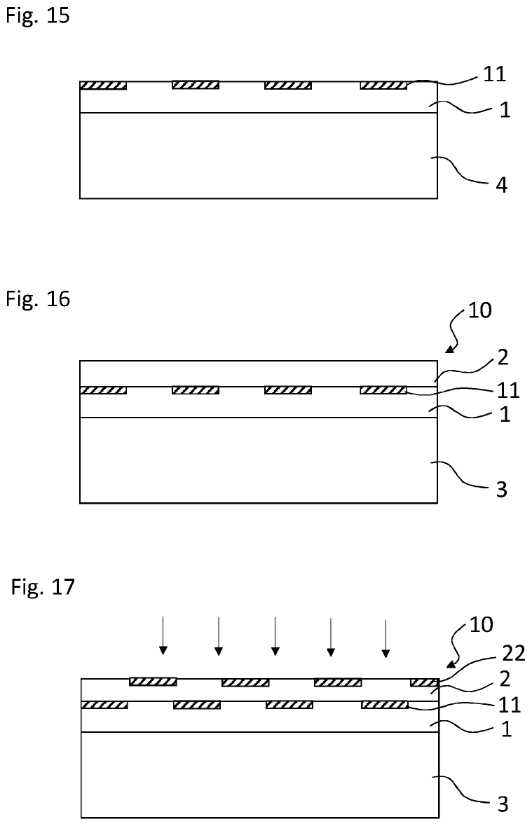

FIGS. 15 to 18 show different positions in a third exemplary embodiment of the method as well as further exemplary embodiments of the semiconductor body,

FIG. 19 shows a further exemplary embodiment of the semiconductor body.

In the position of FIG. 1, a substrate 4, e.g. an n-doped 4H-SiC substrate 4, is provided. The substrate 4 may be a standard 4° off substrate.

In the position of FIG. 2, a first semiconductor layer of SiC, for example 4H-SiC, is epitaxially grown on the substrate 4. The growth may be done by chemical vapor deposition, CVD for short, for example by hot wall chemical vapor deposition, HWCVD for short. For example, the first semiconductor layer 1 is grown to a thickness of about 10 μm. During the growth, the first semiconductor layer 1 may be doped with second-type dopants which, in this case, are n-type dopants.

In the position of FIG. 3, the growth process is interrupted and carbon is introduced into the first semiconductor layer 1, by which a portion of the first semiconductor layer 1 becomes a C-rich region 11. In C-rich region 11, C-atoms or C-ions accumulate at interstitial sites. The C-rich region 11 is only formed in the area of the exposed surface of the first semiconductor layer 1, i.e. at a very low depth so that the C-rich region 11 does not extend over the whole thickness of the first semiconductor layer 1. As an example, this is achieved by implanting the C-ions using plasma ion immersion implantation (PIII). This implantation technique indeed allows very shallow and well defined implantation regions to be formed.

In FIG. 3, the C-rich region 11 extends contiguously over the whole exposed surface of the first semiconductor layer 1.

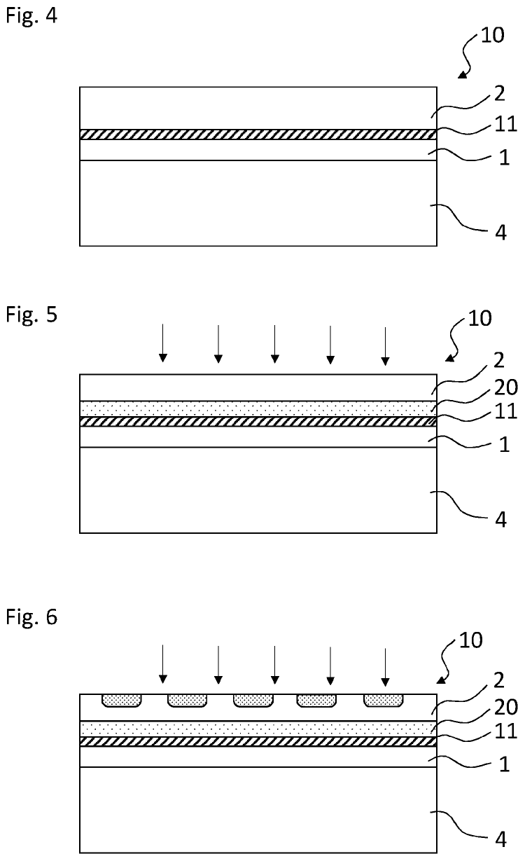

In the position of FIG. 4, a second semiconductor layer 2 is grown on the first semiconductor layer 1, namely directly on the C-rich region 11, until the desired thickness of the semiconductor layer sequence is obtained. The second semiconductor layer 2 is also of SiC, e.g. 4H-SiC. Growth of the second semiconductor layer 2 may be done with the same method as used for the first semiconductor layer 1. Also the second semiconductor layer 2 may be n-doped during growth.

In the position of FIG. 5, an implantation process is performed in which second-type dopants, namely n-type dopants, are implanted into the second semiconductor layer 2 so that a buffer region 20 is formed which adjoins the C-rich region 11. The buffer region 20 has a higher average doping concentration than the first semiconductor layer 1 or the rest of the second semiconductor layer 2. This buffer region 20 compensates strain induced by the carbon in the C-rich region 11.

In contrast to what is shown in FIG. 5, the buffer region 20 can already be produced during the growth of the second semiconductor layer 2.

In the position of FIG. 6, a further implantation process is performed in which first-type dopants (in the present case p-type dopants) are implanted. Here, so-called p-wells are formed in the second semiconductor layer 2.

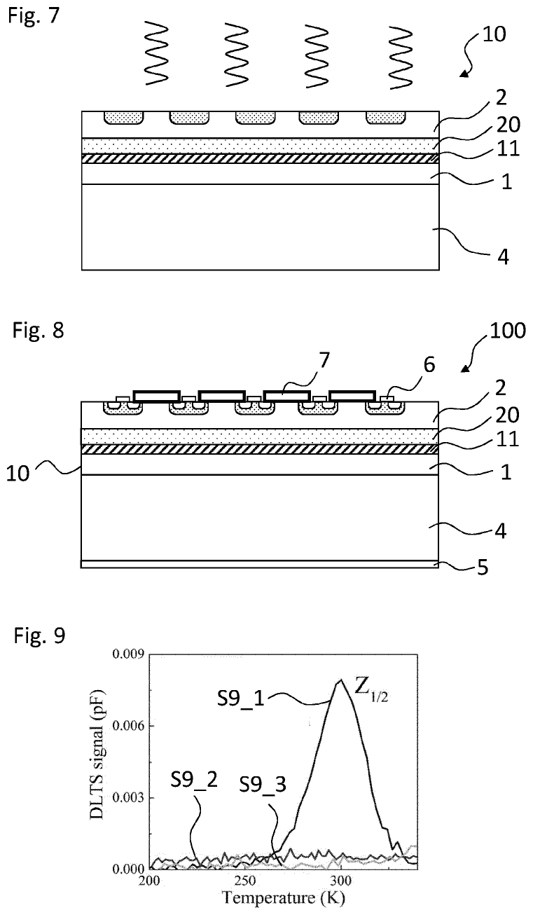

In the position of FIG. 7, an annealing process is performed. The semiconductor body 10 is heated up to a temperature in the range between 1500° C. and 1700° C. in order to activate the previously implanted first-type dopants. During this, the C-atoms or C-ions in the C-rich region 11 at interstitial sites are partially released and fill up the carbon vacancies in the semiconductor body 10.

In the position of FIG. 8, a final power semiconductor device 100 in the form of a MOSFET is shown. This device 100 has been produced by further implanting second-type dopants into the p-wells in order to produce contact regions and by applying main electrodes 5, 6 and a gate electrode 7 onto the semiconductor body 10.

In the position of FIG. 9, the Deep-level transient spectroscopy, DLTS for short, signal is shown for different semiconductor bodies as a function of temperature. Curve S9_1 shows the case of a semiconductor body of SiC for which no measures for reducing carbon vacancies were applied. The curve S9_1 indicates a prominent peak indicating Z_{1/2} vacancies. Curve S9_2 indicates the case when the semiconductor body is treated by oxidation. The carbon vacancies are gone. Curve S9_3 indicates the results obtained when producing the semiconductor body 10 as described before, i.e. by forming a C-rich region 11 by means of PIII. Also in this case, the carbon vacancies are gone.

FIG. 10 indicates the concentration of C-atoms/C-ions at interstitial sites in a C-rich region 11 produced in an SiC layer by using PIII as a function of the depth, i.e. as a function of the distance from the surface of the SiC layer via which the carbon is implanted. The curve S10_1 indicates the concentration of C-atoms/C-ions at interstitial sites before heating to temperatures between 1500° C. and 1700° C. and curve S10_2 shows the concentration after this heating. Due to the heating, some of the C-atoms/C-ions at interstitial sites have recombined with C-vacancies so that the concentration of C-atoms/C-ions at interstitial sites is reduced. As can be seen, the PIII technique produces a very shallow and sharply decreasing concentration profile with the maximum concentration at the surface of the SiC layer at which the carbon enters into the Sic layer.

FIG. 11 shows, as a comparison, the concentration of C-atoms/C-ions at interstitial sites when the C-rich region is formed by deep ion implantation which uses much higher ion energies than PIII. In this case, the maximum of the concentration is inside the SiC layer. The region is thicker and the profile is less steep than in FIG. 10.

FIG. 12 shows a position in the second exemplary embodiment of the method. In this position, several laterally spaced C-rich regions 11 are formed at the exposed surface of the first semiconductor layer 1. This pattern of C-rich regions 11 can be obtained, for example, by using a mask on the first semiconductor layer 1 during the implantation of carbon. The mask is not shown in FIG. 12.

In the position of FIG. 13, a second semiconductor layer 2 is then again grown on the first semiconductor layer 1.

FIG. 14 shows an exemplary embodiment of the final power semiconductor device 100 as produced with the method described in connection with FIGS. 12 and 13. Also in this case, the power semiconductor device 100 is a power MOSFET.

FIG. 15 shows a position in the third exemplary embodiment of the method which is identical to the position of FIG. 12.

In FIG. 16, a second semiconductor layer 2 is grown on the first semiconductor layer 1.

In FIG. 17, carbon is introduced into the second semiconductor layer 2, e.g. again by PIII, so that laterally spaced C-rich regions 22 are formed in the second semiconductor layer 2. Also here, a non-shown mask may be used for obtaining this C-rich region pattern.

As can be seen in FIG. 17, the C-rich regions 22 of the second semiconductor layer 2 and the C-rich regions 11 of the first semiconductor layer 1 are in a staggered configuration in which the regions 11 do not overlap with the regions 22 in a lateral direction.

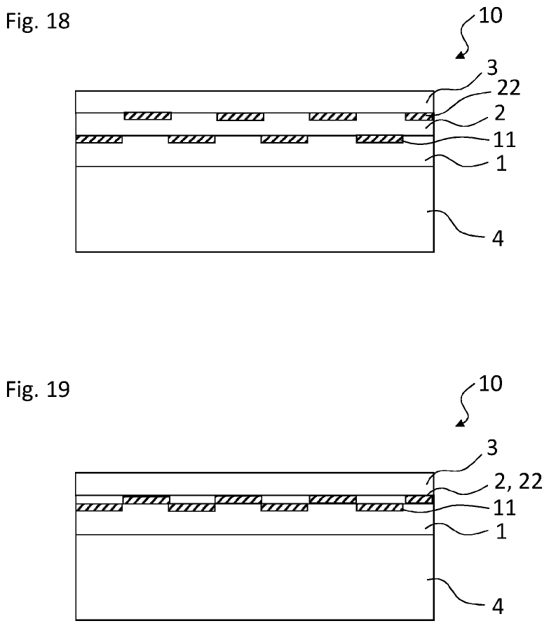

FIG. 18 shows a position in which a third semiconductor layer 3 is grown on the second semiconductor layer 2. The third semiconductor layer 3 is also of SiC and may be grown with the same method as the first and the second semiconductor layer 2.

FIG. 19 shows a further exemplary embodiment of the semiconductor body 10 which is similar to that of FIG. 18. However, in this case, the regions 22 of the second semiconductor layer 2 and the regions 11 of the first semiconductor layer 1 are closer to each other in vertical direction.

The embodiments shown in the FIGS. 1 to 19 as stated represent exemplary embodiments; therefore, they do not constitute a complete list of all embodiments according to the improve method, the improved semiconductor body and the improved power semiconductor device. Actual methods, semiconductor bodies and power semiconductor devices may vary from the embodiments shown in terms of arrangements, elements and layer thicknesses, for example.

### REFERENCE SIGNS

1 first semiconductor layer
2 second semiconductor layer
3 third semiconductor layer
4 substrate
5 main electrode
6 main electrode
7 gate electrode
10 semiconductor body
11 C-rich region
20 buffer region
21 100 power semiconductor device
S9_1 to S9_3 curves
S10_1, S10_2 curves

1. A method for producing a semiconductor body, comprising
providing an n-doped substrate made of SiC,
epitaxially growing a first semiconductor layer of SiC directly on the substrate, the first semiconductor layer is n-doped and an average and/or maximum doping concentration in the first semiconductor layer is smaller than an average and/or minimum doping concentration in the substrate,
introducing carbon into the first semiconductor layer using plasma ion immersion implantation, PIII, so that at least a portion of the first semiconductor layer becomes at least one C-rich region wherein a minimum and/or average concentration of C-atoms or C-ions, respectively, at interstitial sites is at least 100-times greater than a maximum and/or average concentration in the first semiconductor layer before the step of introducing carbon has been performed, and in the C-rich region, the average concentration of C-atoms or C-ions at interstitial sites is at least 10¹⁷ cm⁻³, and a thickness of the C-rich region is at most 100 nm,
epitaxially growing a second semiconductor layer of SiC on the first semiconductor layer comprising the at least one C-rich region, the second semiconductor layer is n-doped,
forming at least one buffer region of the second semiconductor layer adjoining the C-rich region and being n-doped with an average and/or maximum doping concentration being greater than the average and/or maximum doping concentration in the first semiconductor layer, the at least one buffer region is a buffer layer extending contiguously without interruptions over a whole lateral extent of the second semiconductor layer, and
performing a further implantation process in which p-doped p-wells are formed in the second semiconductor layer.

2. The method according to claim 1, wherein
the C-rich region is formed at an exposed side of the first semiconductor layer and such that, after epitaxially growing the second semiconductor layer, the C-rich region lies between the second semiconductor layer and a remaining portion of the first semiconductor layer which has not become C-rich.

3. The method according to claim 1, wherein
the thickness of the C-rich region is at least 15 nm and at most 50 nm.

4. The method according to claim lany one of the preceding claims, further comprising
implanting first-type dopants into the semiconductor layer sequence, said semiconductor layer sequence comprising the first and second semiconductor layer.

5. The method according to claim 4, further comprising
activating the first type-dopants at a temperature of at least 1500° C.

6. The method according to claim 4, wherein
implantation is done with an energy of the C-ions in the range between 1 keV inclusive and 50 keV inclusive.

7. The method according to claim lany one of the preceding elaims, wherein
a plurality of C-rich regions which are laterally spaced from each other is formed in the first semiconductor layer.

8. The method according to claim lany one of the preceding claims, further comprising
introducing carbon into the second semiconductor layer so that at least a portion of the second semiconductor layer becomes at least one C-rich region,
growing a third semiconductor layer of SiC on the second semiconductor layer.

9. The method according to claim 8, wherein
a plurality of C-rich regions which are laterally spaced from each other is formed in the first semiconductor layer,
a plurality of C-rich regions which are laterally spaced from each other is formed in the second semiconductor layer,
the C-rich regions in the first semiconductor layer and the C-rich regions in the second semiconductor layer are arranged in a staggered configuration.

10. A semiconductor body, comprising
an n-doped substrate made of SiC,
a first semiconductor layer of SiC directly on the substrate, the first semiconductor layer is n-doped and an average and/or maximum doping concentration in the first semiconductor layer is smaller than an average and/or minimum doping concentration in the substrate,
a second semiconductor layer of SiC directly on the first semiconductor layer, the second semiconductor layer is n-doped,
at least one C-rich region in the first semiconductor layer,
at least one buffer region of the second semiconductor layer adjoining the C-rich region and being n-doped with an average and/or maximum doping concentration being greater than the average and/or maximum doping concentration in the first semiconductor layer, the at least one buffer region is a buffer layer extending contiguously without interruptions over a whole lateral extent of the second semiconductor layer, and
p-doped p-wells in the second semiconductor layer, wherein
the at least one C-rich region adjoins the second semiconductor layer,
in the C-rich region, the average concentration of C-atoms or C-ions at interstitial sites is at least 10¹⁷ cm⁻³,
the thickness of the C-rich region is at most 100 nm.

11. The semiconductorSemiconductor body according to claim 10, wherein
the at least one C-rich region has its maximum concentration of C-atoms or C-ions at interstitial sites at the interface to the second semiconductor layer.

12. The semiconductor body according to claim 10, wherein
the average concentration of C-vacancies in the second semiconductor layer is at most 10¹² cm⁻³.

13. The semiconductor body according to claim 10, wherein
the average mobility for charge carriers in the second semiconductor layer is at least 100 cm²/Vs at room temperature.

14. A power semiconductor device, comprising
a semiconductor body according to claim 10,
electrodes in electrical contact with the semiconductor body.

15. (canceled)
